(19) United States
(12) Patent Application Publication
(10) Pub. No.: US 2025/0044679 A1
(43) Pub. Date: Feb. 6, 2025

(54) PUPIL FILTER WITH SPATIALLY-VARYING TRANSMISSION

(71) Applicant: KLA Corporation, Milpitas, CA (US)

(72) Inventor: Alexander Pokrovskiy, Mountain View, CA (US)

(21) Appl. No.: 18/228,643

(22) Filed: Jul. 31, 2023

(51) Int. Cl. G03F 1/84; G01N 21/956; G03F 1/24; G03F 7/00

(52) U.S. Cl. CPC G03F 1/84; G01N 21/956; G03F 1/24; G03F 7/70033; G01N 2021/95676

(57) ABSTRACT

An inspection system includes a pupil filter positioned in an imaging pupil of the inspection system. The pupil filter is configured to provide spatially-varying intensity transmission. The pupil filter is a slab of glass with a patterned layer disposed on a surface of the slab of glass. The inspection system introduces a spatially-varying intensity transmission using the pupil filter.

### FIELD OF THE DISCLOSURE

This disclosure relates to inspection of masks used for semiconductor manufacturing, such as measurement of extreme ultraviolet (EUV) marks to detect defects.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a workpiece, such as a semiconductor wafer, using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Inspection processes are used at various steps during semiconductor manufacturing to detect defects on workpieces to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the workpieces, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

Inspection of extreme ultraviolet (EUV) reticles used for EUV lithography can be difficult. Currently inspection systems cannot detect certain defects. Defectivity control of the EUV reticles, which define the patterns printed on semiconductor wafers or other workpieces, plays a critical role from a process yield management perspective. However, defect detection has been regarded as one of the high risk areas of EUV lithography development because of the lack of a reliable actinic EUV photomask inspector that optically inspects the photomask at the same wavelength that the EUV scanner uses (e.g., 13.5 nm). Electron-beam inspection tools, which can offer a good sensitivity, typically have an inspection throughput that is orders of magnitude slower than what is desired and are not a practical solution for inspection. Currently, and for the foreseeable future, the inspection of patterned EUV reticles may rely on the more available, higher throughput inspection tools operating within the deep-UV (DUV) wavelength range (1.90-260 nm).

Such dramatic difference in wavelengths between the inspection and lithography systems can affect the performance of a DUV inspection system as applied to EUV reticle defect detection. For example, the DUV inspection system has an inferior optical resolution as compared to the EUV lithography scanner, resulting in a lower image contrast. Additionally, the different materials from which the EUV reticle (e.g., multilayer (ML) background materials versus absorber material pattern) is composed have different optical properties between EUV and DUV wavelengths, which influences the amplitude and phase of the light reflected from the EUV reticle. In a more specific example, the defect sensitivity may be compromised because the light scattered from the defect tends to be out of phase with the light reflected from the background pattern. Such effect has been a limiting factor in determining the achievable EUV photomask detect detection sensitivity of the DUV inspection systems.

Improved systems and techniques are needed.

### BRIEF SUMMARY OF THE DISCLOSURE

An inspection system is provided in a first embodiment. The inspection system includes a light source that generates a beam of light; illumination optics configured to direct the beam of light onto an EUV reticle; a pupil filter positioned in an imaging pupil of the inspection system; a detector that receives an output beam from the pupil filter and is configured to generate an image for the output beam; and collection optics for directing the output beam that is reflected and scattered from the EUV reticle in response to the beam of light. The pupil filter is configured to provide spatially-varying intensity transmission. The pupil filter is a slab of glass with a patterned layer disposed on a surface of the slab of glass. The output beam is directed through the pupil filter toward the detector.

The patterned layer can include at least two different shapes and/or sizes across the surface.

The patterned layer can have a varying density across the surface.

The patterned layer may be rotationally symmetric or rotationally asymmetric across the surface.

The patterned layer can be chrome, another metal, or a dielectric.

The pupil filter can be configured to provide phase contrast in the output beam. In an instance, the slab of glass has an etched portion having a depth corresponding to an amount of phase change that is introduced into a portion of the output beam that is transmitted through the pupil filter. The patterned layer can be disposed on a side of the slab of glass opposite from the etched portion.

The patterned layer can have a ring with a width from 100 nm to 5000 nm.

The patterned layer can have a ring with a thickness from 10 nm to 250 nm.

The patterned layer can have a spacing between rings from 100 nm to 5000 nm.

A method of inspecting an extreme ultraviolet (EUV) reticle is provided in a second embodiment. The method includes using an inspection system to obtain a test image from an output beam that is reflected and scattered from a test portion of an EUV test reticle. The inspection system is configured to provide a spatially-varying intensity transmission. The inspection system introduces the spatially-varying intensity transmission using a pupil filter that is a slab of glass with a patterned layer disposed on a surface of the slab of glass. A reference image is obtained for a reference reticle portion that is designed to be identical to the test reticle portion. Using a processor, the test image and the reference image are compared. Using the processor, whether the test reticle portion has a candidate defect is determined based on the comparing.

The method can include repeating the using the inspection system, the obtaining a reference image, the comparing, and the determining for each of a plurality of test reticle portions of the reticle. A defect report can be generated based on the candidate defects that have been determined to be present.

The patterned layer can include at least two different shapes and/or sizes across the surface.

The patterned layer can have a varying density across the surface.

The patterned layer may be rotationally symmetric or rotationally asymmetric across the surface.

The pupil filter can be configured to provide phase contrast in the output beam. In an instance, the slab of glass has an etched portion having a depth corresponding to an amount of phase change that is introduced into a portion of the output beam that is transmitted through the pupil filter.

### DESCRIPTION OF THE DRAWINGS

For a fuller understanding of the nature and objects of the disclosure, reference should be made to the following detailed description taken in conjunction with the accompanying drawings, in which:

FIG. 1 is a diagrammatic representation of an inspection system that is configured for imaging in accordance with an embodiment of the disclosure;

FIG. 2 is a cross-sectional diagrammatic representation of a side view of a pupil filter in accordance with an embodiment of the disclosure;

FIG. 3 is a cross-sectional diagrammatic representation of a side view of a pupil filter in accordance with another embodiment of the disclosure;

FIG. 4 shows an exemplary spatially-varying transmission characteristics for rotationally symmetric transmission of the pupil filter;

FIG. 5 shows exemplary patterns of the patterned layer of the pupil filter;

FIG. 6 is a cross-sectional diagrammatic representation of a side view of a pupil filter in accordance with another embodiment of the disclosure wherein the patterned layer has different shapes and/or sizes;

FIG. 7 is a cross-sectional diagrammatic representation of a side view of a pupil filter in accordance with another embodiment of the disclosure wherein the patterned layer has varying density;

FIG. 8 is a cross-sectional diagrammatic representation of a side view of a pupil filter in accordance with another embodiment of the disclosure wherein the patterned layer is asymmetric; and

FIG. 9 is a flowchart showing an embodiment of a method in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

To enhance the defect signature in images (and increase chances of detecting the defect), a pupil filter (PF) is used in an inspection system. Embodiments of the pupil filter disclosed herein provided improved results during testing. The pupil filter can have a spatially-varying intensity transmission that enhances the defect signal. The shape of the spatially-varying transmission distribution can enhance the defect signal.

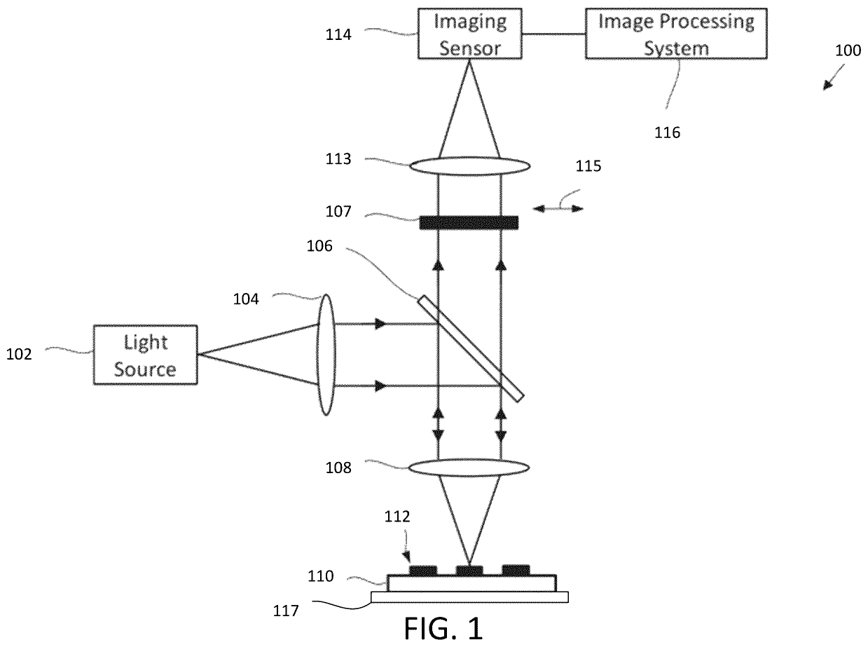

Any suitable combination of hardware and software may be used to implement spatially-varying intensity transmission for reticle inspection. FIG. 1 is a diagrammatic representation of an inspection system 100 that is configured for spatially-varying intensity transmission imaging. This inspection system 100 generally includes a light source 102 that is suitable for inspection of an EUV reticle. One example of a light source is a quasi-continuous wave laser. In certain embodiments, a light source may generally provide high pulse repetition rate, low-noise, high power, stability, reliability, and extendibility. While an EUV scanner operates at 13.5 nm wavelength, an inspection system for an EUV reticle does not have to operate at the same wavelength. A TERON system from KLA Corporation, for example, operating at 193 nm can be used to inspect EUV reticles.

The inspection system 100 can generally be set up with a set of operating parameters or a “recipe.” Recipe settings may include one or more of the following settings: pupil filter configuration, zoom settings, one or more defect detection threshold values, a focus setting, an illumination or detection aperture setting, an incident beam angle and wavelength setting, a detector setting, a setting for the amount of reflected or transmitted light, aerial modeling parameters, etc. Certain embodiments of the present invention utilize an inspection system in reflection mode and having a set polarization, such as S, P, circular, etc.

The inspection system 100 includes a collection of optical elements for focusing an illuminating light beam onto the inspected surface 112. For instance, the inspection system 100 may include a beam steering device for precise beam positioning and a beam conditioning device, which can be used to provide light level control, speckle noise reduction, and high beam uniformity. Beam steering and/or beam conditioning devices may be separate physical devices from, for example, a laser. For brevity, FIG. 1 illustrates only a condenser lens 104, a beam splitter 106, and an objective lens 108 for the illumination optics. However, one skilled in the art would understand that an inspection system can include other optical or electronic elements for achieving specific inspection functions. The objective lens 108 may be relatively large in order to meet specific low aberration requirements. The objective lens can be adjusted to different sizes of pixels, such as less than about 100 nm for each pixel or, more particularly, less than about 75 nm or even less than 60 nm.

The sample 110 may also be placed on a stage 117 of the inspection system 100, and the inspection system 100 may also include a positioning mechanism for moving the stage 117 (and sample 110) relative to the incident beam. By way of examples, one or more motor mechanisms may each be formed from a screw drive and stepper motor, linear drive with feedback position, or band actuator and stepper motor. The sample 110 can be an EUV reticle or photomask or another type of workpiece (e.g., a semiconductor wafer or a flat panel).

After the incident beam(s) impinge on the sample 110, the light may then be reflected and diffracted/scattered from the sample 110 in the form of “output light” or an “output beam.” The inspection system 100 also includes any suitable lens arrangements for directing the output light towards one or more detectors. As shown, an output beam can be received by a detector or imaging lens 113, which directs the output beam towards a detector 114. In an embodiment, the detector 114 is a time delay integration (TDI) detector. A typical TDI detector accumulates multiple exposures of the same area of the inspected surface, effectively increasing the integration time available to collect incident light. In general, the detector 114 may include transducers, collectors, charge-coupled devices (CCDs), or other types of radiation sensors.

When imaging a reticle as the sample 110, one can analyze the light from both the ML and absorber materials. For instance, the Kirchhoff complex reflection coefficients at 193 nm wavelength for both the ML and absorber can be calculated. This calculation shows that the absorber has a reflection amplitude approximately half of that of the ML and that there is a −90° phase angle difference between them, indicating that the EUV mask is a strong phase object. It should be noted that the EUV absorber stack film thickness and type may vary in practice. The phase nature of the mask generally persists with certain variability in the exact phase angle.

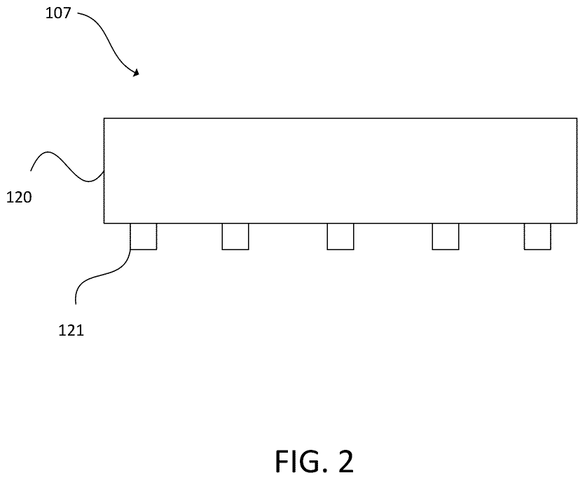

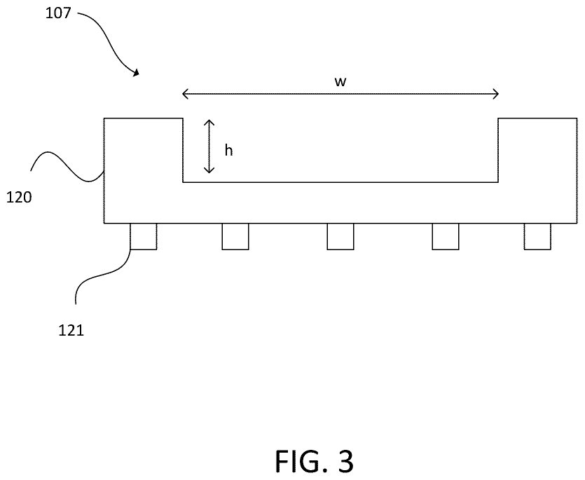

In FIG. 1, the inspection system 100 includes a pupil filter 107 to provide spatially-varying intensity transmission of the output light. The pupil filter 107 can be an apodizer. The pupil filter 107 may be fabricated by etching into a thin slab of glass 120, such as fused silica. FIGS. 2 and 3 are diagrammatic representations of a side view of a pupil filter 107. As shown in FIG. 3, the etch depth or height h determines the phase of the filter relative to the unetched area. For example, at 19.3 nm, an etch depth of approximately 85 nm would give a phase angle close to 90°.

The geometry of the pupil filter 107 is configured to match the shape of the illumination aperture. That is, the pupil filter 107 is configured to provide spatially-varying intensity transmission with or without a phase change within the illumination area, which also corresponds to a reflected portion of the output light, while not providing these effects outside such illumination area, which corresponds mostly to the scattered light. In the example of FIG. 3, the width (w) of the etched portion can be sized to match the aperture diameter, such as a sigma 0.5 aperture. The sigma 0.5 illumination and circular polarization is chosen here as an example to illustrate the impact of the phase contrast imaging. The phase contrast imaging can enhance a signal strength of a phase object as compared to a non-phase or differently phased object in the test reticle portion. Other illumination options for EUV photomask inspection are possible.

Accordingly, the pupil filter 107 can be configurable to different phase change values. For instance, different pupil filters 107 with different etched depths and resulting phase change values can be selectively inserted into the imaging pupil plane along directions 115, as well as removing all pupil filters from the pupil plane for an inspection without phase contrast, such as for pinhole defect detection. While optional, phase contrast imaging can improve defect classification, which relies on the information contained in the defect residual image. For example, for a EUV contact pattern, an oversize detect will tend to have a bright tone, while an undersize or an intrusion defect tend to have a dark tone. The defect intensity tone at the best focus may be incorrect for undersize and intrusion without phase contrast, but is correct with phase contrast. Thus, phase contrast imaging can provide a more accurate defect classification result for certain applications because the intensity tone is correct for all defect types.

While the embodiment in FIG. 3 is shown with the etch portion in the slab of glass 120, the patterned layer 121 can be used with a slab of glass 120 that is not etched and does not provide phase contrast. An example without phase contrast is shown in FIG. 2.

An anti-reflection coating (such as MgF₂, etc.) may be deposited on one or both sides of the slab of glass 120 to reduce stray light. The transmission of the pupil filter 107 is typically left unchanged, but it also may be controlled by placing a patterned layer 121 on a flat side of the slab of glass 120, made by material compatible with DUV light, such as chrome, aluminum, nickel, another metal, or a dielectric. FIGS. 2 and 3 show a side view of a pupil filter 107 having a patterned layer 121 for controlling transmission. The patterned layer 121 can vary in size and spacing so as to provide spatially-varying intensity transmission to improve the defect detection sensitivity for certain defect types or mask pattern types.

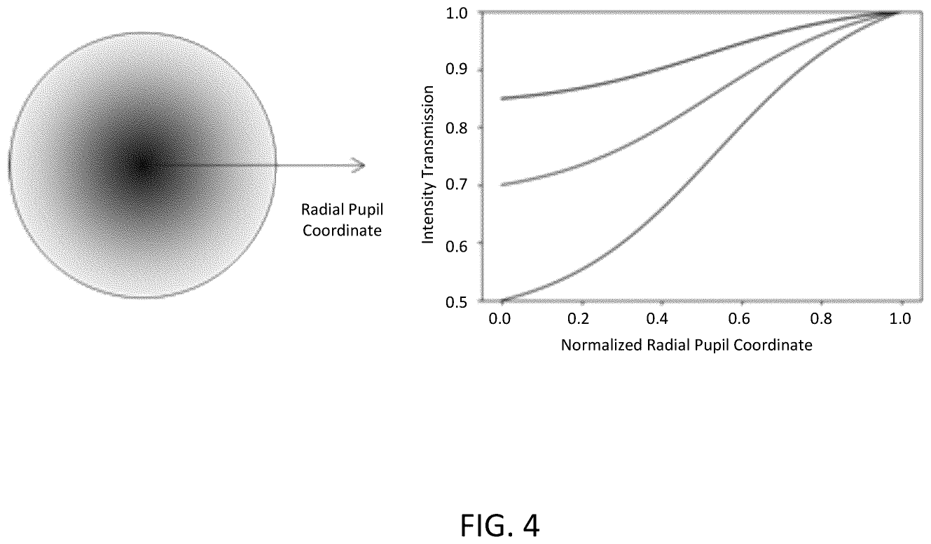

FIG. 4 shows an exemplary spatially-varying transmission characteristics for rotationally symmetric transmission of the pupil filter 107. The lines on the chart show gradual transmission. Intensity transmission lines show total transmission through the pupil filter (i.e., the slab of glass 121 with the patterned layer 121).

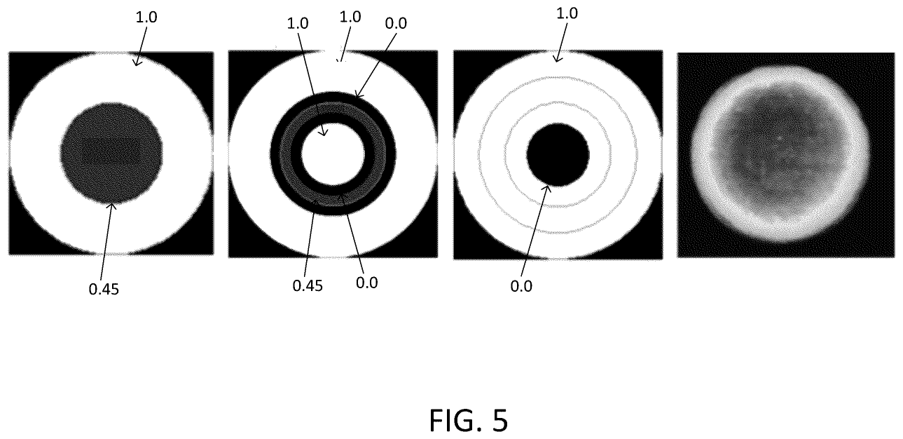

FIG. 5 shows exemplary patterns of the patterned layer 121 of the pupil filter 107. On the left, the two sections show 100% transmission (1.0) and 45% transmission (0.45). This is a step function. The different patterns in FIG. 5 can be used to enhance different mask defect types. As seen in FIG. 5, the patterned layer 121 can be ring (e.g., concentric rings), but other shapes are possible. While the rings in FIG. 5 are shown as solid and unbroken, the rings also can be segmented.

The middle left example in FIG. 5 shows another step function. The progression goes 100% transmission, 0% transmission, 45% transmission, 0% transmission, and 100% transmission from inner to outer.

The middle right example in FIG. 5 shows 0% transmission in the center and 100% at the edge.

The right example in FIG. 5 shows an asymmetric transmission pattern. An asymmetric transmission pattern can be used to correct for errors in the inspection system 100.

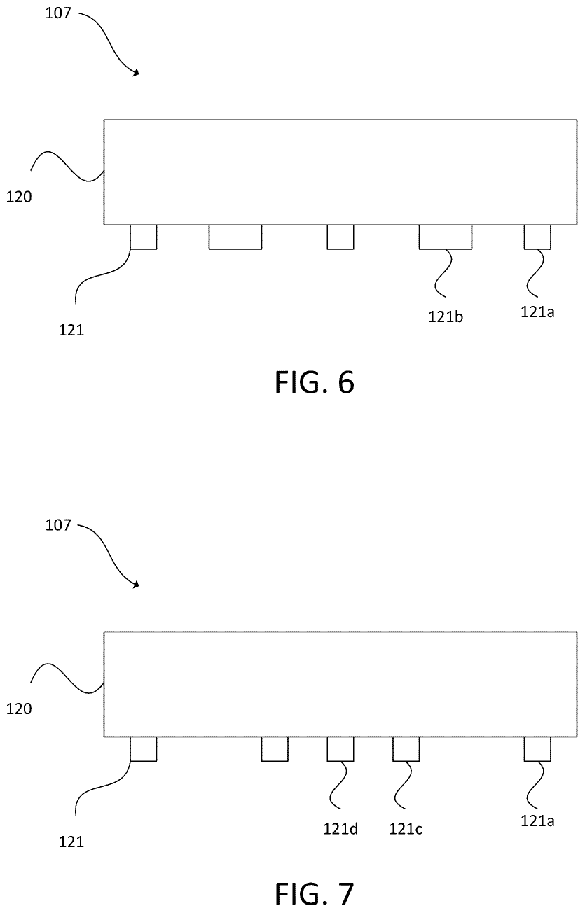

In an embodiment, the patterned layer 121 includes at least two different shapes and/or sizes across the surface of the slab of glass 120. This is shown in FIG. 6. The ring 121a and the ring 121b have different widths. Different widths can block different amount of light and, thus, produce spatially varying transmission. Other examples are shown with the differing ring thicknesses in FIG. 5. The width of a ring in the patterned layer 121 can be from 100 nm to 5000 nm. A ring in the patterned layer 121 or other features of the patterned layer 121 can have a thickness extending from a surface of the slab of glass 120 that is from 10 nm to 250 nm. These widths and thickness can enhance the defect signature in images. While disclosed with respect to a ring or circle, these dimensions also can apply to other shapes. The dimensions can vary between features of the patterned layer 121. Thus, the patterned layer 121 may not have uniform widths or thicknesses.

In an embodiment, the patterned layer 121 includes a varying density across the surface of the slab of glass 120. This is shown in FIG. 7. The ring 121a is spaced differently from the ring 121c than the ring 121c is spaced from the circle 121d. For example, higher density will result in lower transmission value. Other examples are shown with the differing spacing in FIG. 5. The varying density of FIG. 7 can be combined with the different shapes and/or sizes of FIG. 6. The spacing between rings of the patterned layer 121 can be from 100 nm to 5000 nm. This spacing can enhance the defect signature in images. While disclosed with respect to a ring or circle, this spacing also can apply to other shapes. The spacing can vary between features of the patterned layer 121. Thus, the patterned layer 121 may not have uniform spacing.

In an embodiment, the patterned layer 121 is rotationally symmetric across the surface of the slab of glass 120. This is, for example, shown in FIGS. 2, 3, 6, and 7.

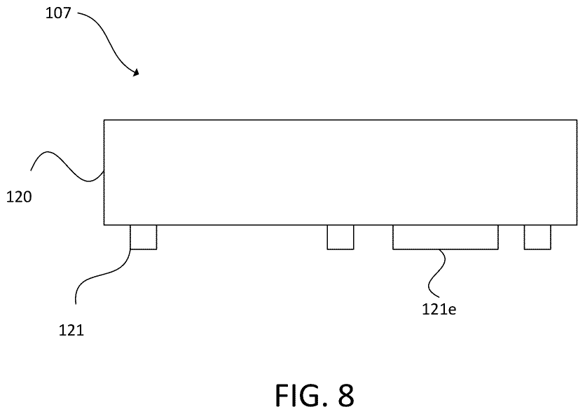

In an embodiment, the patterned layer 121 is rotationally asymmetric across the surface of the slab of glass 120. This is, for example, shown in the right-most example in FIG. 5 or FIG. 8. In FIG. 8, the patterned layer 121 includes a circle 121e that is only present on part of the surface.

In another example, the patterned layer 121 in a single monolithic layer across the slab of glass 120 with different thicknesses at different points on the surface. The single monolithic layer can be symmetric or asymmetric. Apertures can be formed in the single monolithic layer.

Multiple pupil filters 107 can be used in a given inspection system. The choice of which particular pupil filter is used in an inspection pass can depend on the specifics of the EUV mask stack and defect types to be detected. Multiple inspection passes, each performed with a different pupil filter, may be initially performed in order to achieve the optimal overall inspection sensitivity for all critical detect types. A set of pupil filters 107 can be provided in the imaging path. During the inspection, while a particular swath N is being processed, a processor can analyze the database corresponding to swath N+1 and recommend the best pupil filter for that swath. The filter may be selected for optically scanning swath N+1. That is, a filter may be selected for a next swath based on the results of using one or more (or multiple) pupil filters on a current or previous swath or other reticle area.

A defect report for the candidate defects can be generated and stored. The defect report may be in any suitable format. In an implementation, the defect report may contain a reference to an image and location for each candidate defect. The defect report may contain a difference between the test and reference images for each candidate defect. An image and location of each candidate defect may also be stored with the defect report for later review. In another example, the detect report is in the form of an image comprised of intensity differences that were defined or flagged as potential defects. The report may be in the form of a defect map having varying colors that correspond to varying intensity or average intensity differences for the candidate defects as further described below.

Referring back to the inspection system of FIG. 1, the illumination beam may be directed towards the sample surface 112 at a substantially normal angle with respect to the inspected surface. In other embodiments, an illuminating light beam can be directed at an oblique angle, which allows separation of the illuminating and reflected beams.

The detector 114 is typically also coupled with a processor 116 in an image processing system, which may include an analog-to-digital converter configured to convert analog signals from the detector 114 to digital signals or images for processing. The processor 116 may be configured to analyze intensity, phase, and/or other characteristics of one or more reflected and scattered beams. The processor 116 may be configured (e.g., with programming instructions) to provide a user interface (e.g., a computer screen) for displaying a resultant test image and other inspection characteristics. The processor 116 may also include one or more input devices (e.g., a keyboard, mouse, joystick) for providing input. The processor 116 may also be coupled with the stage for controlling, for example, a sample position (e.g., focusing and scanning), pupil filter configuration, zoom setting, and other inspection parameters and configurations of the inspection system elements. In certain embodiments, the processor 116 is configured to carry out inspection techniques detailed above. The processor 116 typically has one or more processors coupled to input/output ports, and one or more memories via appropriate buses or other communication mechanisms.

Because such information and program instructions may be implemented on a computer system, such a system includes program instructions/computer code for performing various operations described herein that can be stored on a computer readable media. Examples of machine-readable media include, but are not limited to, magnetic media such as hard disks, floppy disks, and magnetic tape; optical media such as CD-ROM disks; magneto-optical media such as optical disks; and hardware devices that are specially configured to store and perform program instructions, such as read-only memory devices (ROM) and random access memory (RAM).

Examples of program instructions include both machine code, such as produced by a compiler, and files containing higher level code that may be executed by the computer using an interpreter.

It should be noted that the above description and drawings are not to be construed as a limitation on the specific components of the inspection system 100 and that the inspection system 100 may be embodied in many other forms. For example, it is contemplated that the inspection or measurement tool may have any suitable features from any number of known imaging or metrology tools arranged for detecting defects and/or resolving the critical aspects of features of a reticle or workpiece (e.g., a semiconductor wafer). By way of example, an inspection or measurement tool may be adapted for bright field imaging microscopy, dark field imaging microscopy, full sky imaging microscopy, phase contrast microscopy, polarization contrast microscopy, and coherence probe microscopy. It is also contemplated that single and multiple image methods may be used in order to capture images of the target. These methods include, for example, single grab, double grab, single-grab coherence probe microscopy (CPM) and double grab CPM methods. Non-imaging optical methods, such as scatterometry, may also be contemplated as forming part of the inspection or metrology apparatus.

In other inspection applications, the incident light or detected light may be passed through any suitable spatial aperture to produce any incident or detected light profile at any suitable incident angles. By way of examples, programmable illumination or detection apertures may be utilized to produce a particular beam profile, such as dipole, quadrapole, quasar, annulus, etc. In a specific example, pixelated illumination techniques may be implemented. Programmable illuminations and special apertures can serve the purpose of enhancing feature contrast for certain patterns on the reticle, in addition to any of the phase contrast techniques described above.

The inspection system 100 may be suitable for inspecting semiconductor devices or wafers and optical reticles, as well as EUV reticles or masks. Other types of samples which may be inspected or imaged using the inspection apparatus and techniques of the present invention include any surface, such as a flat panel display.

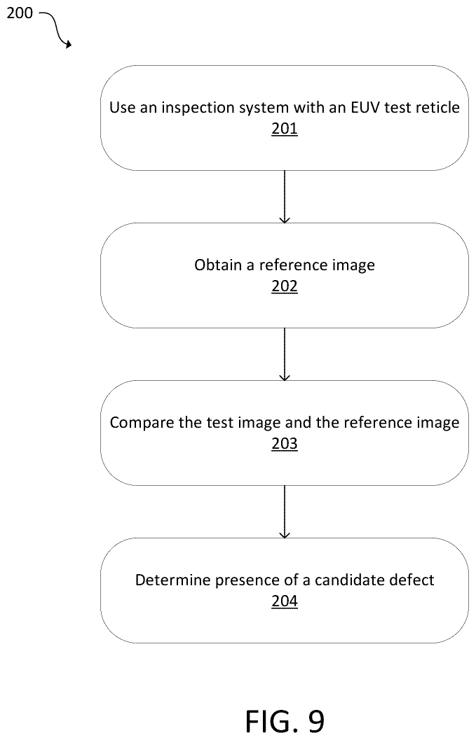

FIG. 9 is a flowchart showing the method 200 for inspecting an EUV reticle. At 201, an inspection system is used to obtain a test image from an output beam that is reflected and scattered from a test portion of an EUV test reticle. The inspection system can be an embodiment of the inspection system 100. The inspection system can be configured to provide a spatially-varying intensity transmission to enhance a signal from any defects as compared to a signal from noise on the EUV reticle. The inspection system can introduce the spatially-varying intensity transmission (and, optionally, phase contrast) using a pupil filter that is a slab of glass with a patterned layer disposed on a surface of the slab of glass. The pupil filter (implemented via the patterned layer or unpatterned layer of varying thickness) enhances the relative amount of light in the image spatial frequencies that amplify signature of specific mask defects. When an embodiment of the disclosed pupil filter is incorporated in the inspection system, mask defects in the images appear more prominently and stand out more clearly above the background image acquisition noise. With the defect signature enhanced over the image noise by the pupil filter, such defects can be detected in the images and reported.

A reference image for a reference reticle portion that is designed to be identical to the test reticle portion is obtained at 202.

The test image and the reference image are compared at 203. Whether the test reticle portion has a candidate defect is determined at 204 based on the comparing.

Using the inspection system at 201, obtaining a reference image at 202, comparing at 203, and determining at 204 can be repeated for multiple test reticle portions of the reticle. A defect report can be generated based on the candidate defects that have been determined to be present.

Thus, the operations may be repeated for each reticle area so that the entire reticle is inspected. After the reticle is inspected, it may then be determined whether the reticle passes inspection. Each image difference or intensity value difference that is above a predefined threshold may then be more carefully reviewed to determine whether the reticle is defective and can no longer be used. For example, a scanning electron microscope (SEM) may be used to review each detect candidate to determine whether critical dimensions (CDs) are out of specification. This review process may be implemented on any or all of the reported candidate defects.

Regardless of the inspection approach that is implemented, if the reticle does not pass review, the corresponding reticle can either be repaired or discarded and the inspection ends. For example, certain defects can be cleaned from the reticle.

If the reticle passes, the review process may end without discarding or repairing the reticles. The passing reticle may be used to fabricate workpieces (e.g., semiconductor wafers). After a reticle (repaired or passing reticle) is again used, the reticle may again be inspected.

In an alternative embodiment, if the reticle passes inspection, all the candidate defects can be deemed “acceptable differences,” and such acceptable difference values can be stored and later reused to quickly requalify the reticle after such reticle has been used. In this example, the “acceptable differences” are used as a set of baseline events. If such baseline events are present on a used reticle, such baseline events can be deemed acceptable and not reported as candidate defects. Only differences that have occurred since the baseline events were detected are determined to be candidate defects and subject to defect review.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. An inspection system comprising:
a light source that generates a beam of light;
illumination optics configured to direct the beam of light onto an extreme ultraviolet (EUV) reticle;
a pupil filter positioned in an imaging pupil of the inspection system, wherein the pupil filter is configured to provide spatially-varying intensity transmission, and wherein the pupil filter is a slab of glass with a patterned layer disposed on a surface of the slab of glass;
a detector that receives an output beam from the pupil filter and is configured to generate an image for the output beam; and
collection optics for directing the output beam that is reflected and scattered from the EUV reticle in response to the beam of light, wherein the output beam is directed through the pupil filter toward the detector.

2. The inspection system of claim 1, wherein the patterned layer includes at least two different shapes and/or sizes across the surface.

3. The inspection system of claim 1, wherein the patterned layer has a varying density across the surface.

4. The inspection system of claim 1, wherein the patterned layer is rotationally symmetric across the surface.

5. The inspection system of claim 1, wherein the patterned layer is rotationally asymmetric across the surface.

6. The inspection system of claim 1, wherein the patterned layer is chrome, another metal, or a dielectric.

7. The inspection system of claim 1, wherein the pupil filter is further configured to provide phase contrast in the output beam.

8. The inspection system of claim 7, wherein the slab of glass has an etched portion having a depth corresponding to an amount of phase change that is introduced into a portion of the output beam that is transmitted through the pupil filter.

9. The inspection system of claim 8, wherein the patterned layer is disposed on a side of the slab of glass opposite from the etched portion.

10. The inspection system of claim 1, wherein the patterned layer has a ring having a width from 100 nm to 5000 nm.

11. The inspection system of claim 1, wherein the patterned layer has a ring having a thickness from 10 nm to 250 nm.

12. The inspection system of claim 1, wherein the patterned layer has a spacing between rings from 100 nm to 5000 nm.

13. A method of inspecting an extreme ultraviolet (EUV) reticle, the method comprising:
using an inspection system to obtain a test image from an output beam that is reflected and scattered from a test portion of an EUV test reticle, wherein the inspection system is configured to provide a spatially-varying intensity transmission, wherein the inspection system introduces the spatially-varying intensity transmission using a pupil filter that is a slab of glass with a patterned layer disposed on a surface of the slab of glass;
obtaining a reference image for a reference reticle portion that is designed to be identical to the test reticle portion;
comparing, using a processor, the test image and the reference image; and
determining, using the processor, whether the test reticle portion has a candidate defect based on the comparing.

14. The method of claim 13, further comprising:
repeating the using the inspection system, the obtaining the reference image, the comparing, and the determining for each of a plurality of test reticle portions of the reticle; and
generating a defect report based on the candidate defects that have been determined to be present.

15. The method of claim 13, wherein the patterned layer includes at least two different shapes and/or sizes across the surface.

16. The method of claim 13, wherein the patterned layer has a varying density across the surface.

17. The method of claim 13, wherein the patterned layer is rotationally symmetric across the surface.

18. The method of claim 13, wherein the patterned layer is rotationally asymmetric across the surface.

19. The method of claim 13, wherein the pupil filter is further configured to provide phase contrast in the output beam.

20. The method of claim 19, wherein the slab of glass has an etched portion having a depth corresponding to an amount of phase change that is introduced into a portion of the output beam that is transmitted through the pupil filter.
